(19) United States
(12) Patent Application Publication
(10) Pub. No.: US 2024/0072075 A1
(43) Pub. Date: Feb. 29, 2024

(54) ELECTRONIC DEVICE AND MANUFACTURING METHOD OF ELECTRONIC DEVICE

(71) Applicants: InnoCare Optoelectronics Corporation, Tainan City (TW); Innolux Corporation, Miaoli County (TW)

(72) Inventors: Chin-Chi Chen, Tainan City (TW); Ting-Yu Chen, Tainan City (TW); Yi-Ju Tseng, Tainan City (TW); Ji-Zhen Lu, Tainan City (TW)

(73) Assignees: InnoCare Optoelectronics Corporation, Tainan City (TW); Innolux Corporation, Miaoli County (TW)

(21) Appl. No.: 18/354,617

(22) Filed: Jul. 18, 2023

(30) Foreign Application Priority Data
Aug. 25, 2022 (TW) 111131977

(51) Int. Cl. H01L 27/144

(52) U.S. Cl. CPC H01L 27/1443

(57) ABSTRACT

An electronic device including a substrate, a first electrode layer, a photodiode, an insulating layer, a second electrode layer, and a first transparent conductive layer is provided. The first electrode layer is disposed on the substrate. The photodiode is disposed on the first electrode layer and is electrically connected to the first electrode layer. The insulating layer is disposed on the photodiode. The second electrode layer is disposed on the insulating layer and is electrically connected to the photodiode. The first transparent conductive layer is disposed on the insulating layer and contacts the second electrode layer. A manufacturing method of an electronic device is also provided.

### CROSS-REFERENCE TO RELATED APPLICATION

This application claims the priority benefit of Taiwan application serial no. 111131977, filed on Aug. 25, 2022. The entirety of the above-mentioned patent application is hereby incorporated by reference herein and made a part of this specification.

### BACKGROUND

### Technical Field

The disclosure relates to an electronic device and a manufacturing method of an electronic device

### DESCRIPTION OF RELATED ART

The layers used in an electronic device are formed by using corresponding photomasks and corresponding processes. As the number of layers to be formed increases, the manufacturing costs of the electronic device will also increase accordingly.

### SUMMARY

The disclosure provides an electronic device and a manufacturing method of an electronic device, through which the manufacturing costs of the electronic device may be lowered.

According to an embodiment of the disclosure, an electronic device includes a substrate, a first electrode layer, a photodiode, an insulating layer, a second electrode layer, and a first transparent conductive layer. The first electrode layer is disposed on the substrate. The photodiode is disposed on the first electrode layer and is electrically connected to the first electrode layer. The insulating layer is disposed on the photodiode. The second electrode layer is disposed on the insulating layer and is electrically connected to the photodiode. The first transparent conductive layer is disposed on the insulating layer and contacts the second electrode layer.

According to an embodiment of the disclosure, a manufacturing method of an electronic device includes the following steps. A substrate is provided. A first electrode layer is formed on the substrate. A photodiode is formed on the first electrode layer. A second electrode material layer is formed on the photodiode. A first transparent conductive material layer is formed on the photodiode, where the first transparent conductive material layer contacts the second electrode material layer. The second electrode material layer and the first transparent conductive material layer are patterned by using a photomask.

To make the aforementioned more comprehensible, several embodiments accompanied with drawings are described in detail as follows.

### BRIEF DESCRIPTION OF THE DRAWINGS

The accompanying drawings are included to provide a further understanding of the disclosure, and are incorporated in and constitute a part of this specification. The drawings illustrate exemplary embodiments of the disclosure and, together with the description, serve to explain the principles of the disclosure.

FIG. 1 is a schematic cross-sectional view of a portion of an electronic device according to an embodiment of the disclosure.

FIG. 2 is a schematic top view of portions of an electrode layer and a transparent conductive layer in the electronic device according to an embodiment of the disclosure.

FIG. 3 is a schematic cross-sectional view of a portion of an electronic device according to another embodiment of the disclosure.

FIG. 4 is a schematic top view of portions of an electrode layer and a transparent conductive layer in the electronic device according to another embodiment of the disclosure.

FIG. 5 is a flow chart of a manufacturing process of a portion of an electronic device according to an embodiment of the disclosure.

FIG. 6 is a flow chart of a manufacturing process of portions of an electrode layer and a transparent conductive layer according to an embodiment of the disclosure.

FIG. 7 is a schematic cross-sectional view of the manufacturing process of portions of the electrode layer and the transparent conductive layer according to an embodiment of the disclosure.

FIG. 8 is a flow chart of a manufacturing process of a portion of an electronic device according to another embodiment of the disclosure.

FIG. 9 is a flow chart of a manufacturing process of portions of an electrode layer and a transparent conductive layer according to another embodiment of the disclosure.

FIG. 10 is a schematic cross-sectional view of the manufacturing process of portions of the electrode layer and the transparent conductive layer according to another embodiment of the disclosure.

### DESCRIPTION OF THE EMBODIMENTS

The disclosure may be understood by referring to the following detailed description with reference to the accompanying drawings. It is noted that for comprehension of the reader and simplicity of the drawings, in the drawings provided in the disclosure, only a part of the electronic device is shown, and certain devices in the drawings are not necessarily drawn to actual scale. Moreover, the quantity and the size of each device in the drawings are only schematic and exemplary and are not intended to limit the scope of protection provided in the disclosure.

Certain terminologies will be used to refer to specific devices throughout the specification and the appended claims of the disclosure. People skilled in the art should understand that manufacturers of electronic devices may refer to same elements under different names. The disclosure does not intend to distinguish devices with the same functions but different names. In the following specification and claims, the terminologies “including,” “containing,” “having,” etc. are open-ended terminologies, so they should be interpreted to mean “including but not limited to . . . ”. Therefore, when the terms “including,” “containing,” and/or “having” are used in the description of the disclosure, the terminologies designate the presence of a corresponding feature, region, step, operation, and/or element, but do not exclude the presence of one or more corresponding features, regions, steps, operations, and/or elements.

Directional terminologies mentioned herein, such as “top”, “bottom”, “front”, “back”, “left”, “right”, and so forth, refer to directions in the accompanying reference drawings. Accordingly, the directional terminologies provided herein serve to describe rather than limiting the disclosure. In the accompanying drawings, each figure illustrates methods applied in particular embodiments and general features of structures and/or materials in the embodiments. However, these figures should not be construed or defined as the scope covered by the particular embodiments. For instance, relative dimensions, thicknesses, and positions of various layers, regions, and/or structures may be reduced or enlarged for clarity.

When a corresponding element (such as a film layer or a region) is referred to as being “on another element”, the element may be directly on the other element or there may be another element between the two. On the other hand, when an element is referred to as being “directly on another element”, there is no element between the two. Also, when an element is referred to as being “on another element”, the two have a top-down relationship in the top view direction, and the element may be above or below the other element, and the top-down relationship depends on the orientation of the device.

The terminologies “about”, “equal to”, “equivalent to” or “same”, “substantially” or “approximately” are generally interpreted as being within 10% of a given value or range, or interpreted as being within 5%, 3%, 2%, 1%, or 0.5% of a given value or range.

Terminologies such as “first” and “second” used in the specification and the claims are used to modify elements, and the terminologies do not imply and represent that the element(s) have any previous ordinal numbers, nor do they represent the order of a certain element and another element or the order of a manufacturing method. The use of the ordinal numbers is only used to clearly distinguish between an element with a certain name and another element with the same name. The claims and the specification may not use the same terminologies. Accordingly, in the specification, a first element may be a second element in the claims.

It should be understood that the following embodiments may replace, reorganize, and mix the features in several different embodiments to complete other embodiments without departing from the spirit of the disclosure. As long as the features of the embodiments do not violate the spirit of the disclosure or conflict each other, they may be mixed and matched as desired.

An electrical connection or coupling relationship described in this disclosure may refer to a direct connection or an indirect connection. In the case of the direct connection, end points of the elements on two circuits are directly connected or connected to each other by a conductor segment, and in the case of the indirect connection, there are switches, diodes, capacitors, inductors, resistors, other appropriate elements, or a combination of the above elements between the end points of the elements on the two circuits, which should not be construed as a limitation in the disclosure.

In this disclosure, measurement of thickness, length, and width may be done by applying an optical microscope, and the thickness or the width may be obtained by measuring a cross-sectional image in an electron microscope, which should not be construed as a limitation in the disclosure. In addition, certain errors between any two values or directions for comparison may be acceptable. If a first value is equal to a second value, it implies that there may be an error of about 10% between the first value and the second value. If a first direction is perpendicular to a second direction, an angle difference between the first direction and the second direction may be between 80 degrees and 100 degrees; if the first direction is parallel to the second direction, an angle difference between the first direction and the second direction may be between 0 degrees and 10 degrees.

The electronic device of the disclosure may include functions such as detection, displaying, antenna (such as liquid crystal antenna), light emitting, touch sensing, splicing, other suitable functions, or combinations of the above functions, but not limited thereto. The electronic device includes a bendable or flexible electronic device, but not limited thereto. The electronic device may include, for example, liquid crystal, a light emitting diode (LED), a quantum dot (QD), fluorescence, phosphor, other suitable materials, or a combination thereof. The LEDs may include, for example, organic light emitting diodes (OLED), mini LED, micro LED, quantum dot LED, fluorescence, phosphor, or other suitable materials, or a combination of the above, but not limited thereto.

Reference will now be made in detail to the exemplary embodiments of the disclosure, and the same reference numbers are used in the drawings and descriptions to indicate the same or similar parts.

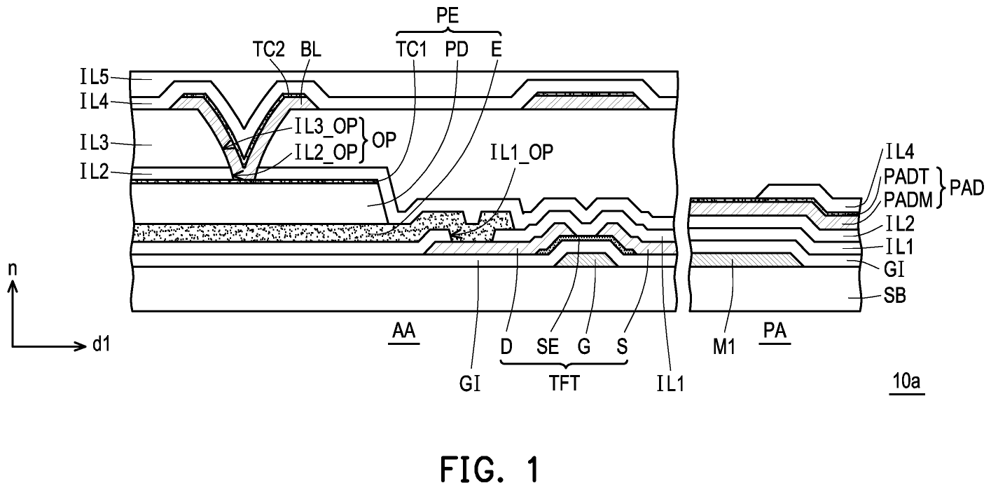

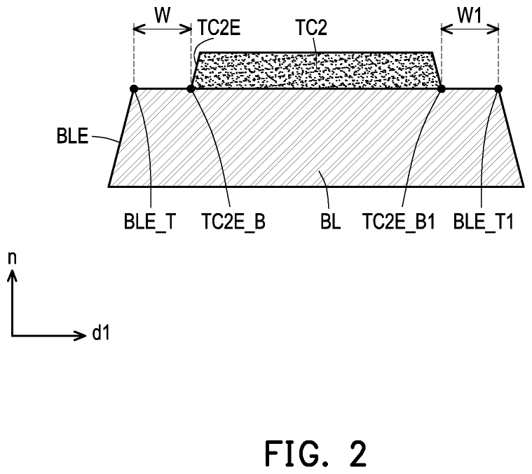

FIG. 1 is a schematic cross-sectional view of a portion of an electronic device according to an embodiment of the disclosure, and FIG. 2 is a schematic top view of portions of an electrode layer and a transparent conductive layer in the electronic device according to an embodiment of the disclosure.

With reference to FIG. 1, an electronic device 10a provided by this embodiment includes a substrate SB, an electrode layer E, a photodiode PD, an electrode layer BL, an insulating layer IL2, and a transparent conductive layer TC2.

The substrate SB may be, for example, a rigid substrate or a flexible substrate, and a material of the substrate SB may be, for example, glass, plastic, or a combination thereof. For instance, the material of the substrate 100 may include quartz, sapphire, polymethyl methacrylate (PMMA), polycarbonate (PC), polyimide (PI), polyethylene terephthalate (PET), other appropriate materials, or combinations of the above materials, which should not be construed as a limitation in the disclosure. In addition, the light transmittance of the substrate SB is not limited in this embodiment, that is, the substrate SB may be a transparent substrate, a semi-transparent substrate, or a non-transparent substrate.

In some embodiments, the electronic device 10a further includes an active element TFT. The active element TFT is disposed on the substrate SB, for example. In some embodiments, the active device TFT includes a gate G, a source S, a drain D, and a semiconductor layer SE, but the disclosure is not limited thereto. A material of the gate G may, for example, include molybdenum (Mo), titanium (Ti), tantalum (Ta), niobium (Nb), hafnium (Hf), nickel (Ni), chromium (Cr), cobalt (Co), zirconium (Zr), tungsten (W), aluminum (Al), copper (Cu), silver (Ag), other suitable metals, or alloys or combinations of the foregoing materials, but the disclosure is not limited thereto. The semiconductor layer SE is disposed on the gate G, for example, and a gate insulating layer GI is disposed between the semiconductor layer SE and the gate G. To be specific, the gate insulating layer GI may, for example, cover the gate G in a normal direction n of the substrate SB, and the semiconductor layer SE may, for example, at least partially overlap the gate G in the normal direction n of the substrate SB. In some embodiments, a material of the semiconductor layer SE may include low temperature polysilicon (LTPS), low temperature polysilicon oxide (LTPO), or amorphous silicon (a-Si), but the disclosure is not limited thereto. For instance, the material of the semiconductor layer SE may include but not limited to amorphous silicon, polycrystalline silicon, germanium; a compound semiconductor (e.g., gallium nitride, silicon carbide, gallium arsenide, gallium phosphide, indium phosphide, indium arsenide, and/or indium antimonide), an alloy semiconductor (e.g., a SiGe alloy, GaAsP alloy, AlInAs alloy, AlGaAs alloy, GaInAs alloy, GaInP alloy, and GaInAsP alloy), or combinations of the foregoing. The material of the semiconductor layer SE may also include but not limited to metal oxide such as indium gallium zinc oxide (IGZO), indium zinc oxide (IZO), indium gallium zinc oxide (IGZTO), or organic semiconductor containing polycyclic aromatic compounds, or combinations of the foregoing. The source S and the drain D are, for example, disposed on the semiconductor layer SE, are separated from each other, and are in direct contact with and electrically connected to the semiconductor layer SE, but the disclosure is not limited thereto. It should be noted that although the active element TFT is shown as a bottom-gate type thin film transistor in this embodiment, the disclosure is not limited to this. In other embodiments, the active element TFT may be a top-gate type thin film transistor known to people skilled in the art.

The electrode layer E is disposed on the substrate SB, for example. In some embodiments, the electrode layer E is electrically connected to the active element TFT. To be specific, the electronic device 10a of this embodiment further includes an insulating layer ILL and the electrode layer E is disposed on the insulating layer ILL In this embodiment, the insulating layer IL1 is disposed on the gate insulating layer GI and partially covers the drain D of the active element TFT, that is, the insulating layer IL1 has an opening IL1_OP exposing part of the drain D. Therefore, the electrode layer E may be electrically connected to the drain D of the active element TFT through the opening IL1_OP, but the disclosure is not limited thereto. In other embodiments, the electrode layer E and the source S and the drain D of the active element TFT belong to the same layer. Therefore, the electrode layer E may directly contact and thus be electrically connected to the drain D. A material of the electrode layer E may, for example, include metals, alloys, metal oxides, or combinations thereof. In some embodiments, the material of the electrode layer E may be indium tin oxide, but the disclosure is not limited thereto. In other embodiments, the material of the electrode layer E may be selected from a metal with high reflectivity, which may reflect ambient light incident to the electronic device 10a from the outside, thereby increasing the amount of photons received by the photodiode PD. A material of the insulating layer IL1 may include, for example, an inorganic material (e.g., silicon oxide, silicon nitride, silicon oxynitride, or a stack layer having at least two of the above materials), an organic material (e.g., polyimide resin, epoxy resin, or acrylic resin), or combinations of the foregoing, but the disclosure is not limited thereto.

The photodiode PD is disposed on the electrode layer E and is electrically connected to the electrode layer E, for example. In some embodiments, the photodiode PD may be electrically connected to the drain D of the active element TFT through the electrode layer E, so that the active element TFT may be used to drive the photodiode PD. To be specific, the photodiode PD may convert the received photons into carriers (e.g., electrons and/or electron holes), and the carriers are stored in the photodiode PD when the active element TFT is not turned on. After the active element TFT is turned on, the carriers stored in the photodiode PD may be read, for example, through a read line (not shown) electrically connected to the active element TFT, so that the function of light detection is achieved. In some embodiments, a material of the photodiode PD includes a semiconductor. For instance, the material of the photodiode PD may include silicon (Si), germanium (Ge), gallium arsenide (GaAs), indium gallium arsenide (InGaAs), cadmium telluride (CdTe), cadmium sulfide (CdS), or combinations thereof, or other suitable semiconductors, but the disclosure is not limited thereto. In some embodiments, the photodiode PD may include a stacked structure of an intrinsic semiconductor layer and an extrinsic semiconductor layer. For instance, the photodiode PD may include a p-type semiconductor layer, an intrinsic semiconductor layer, and an n-type semiconductor layer sequentially stacked in this order in the normal direction n of the substrate SB, but the disclosure is not limited thereto. In other embodiments, the photodiode PD may include an n-type semiconductor layer, an intrinsic semiconductor layer, and a p-type semiconductor layer sequentially stacked in this order in the normal direction n of the substrate SB.

The insulating layer IL2 is disposed on the photodiode PD, for example. In this embodiment, the insulating layer IL2 is disposed on the insulating layer IL1 and the photodiode PD and partially covers the photodiode PD. That is, the insulating layer IL2 has an opening IL2_OP exposing a part of the photodiode PD. A material of the insulating layer IL2 may include, for example, an inorganic material (e.g., silicon oxide, silicon nitride, silicon oxynitride, or a stack layer having at least two of the above materials), an organic material (e.g., polyimide resin, epoxy resin, or acrylic resin), or combinations of the foregoing, but the disclosure is not limited thereto.

In some embodiments, the electronic device 10a further includes a transparent conductive layer TC1. The transparent conductive layer TC1 is, for example, disposed between the insulating layer IL2 and the photodiode PD and is electrically connected to the photodiode PD. A material of the transparent conductive layer TC1 may be, for example, metal oxide. In some embodiments, the material of the transparent conductive layer TC1 is indium tin oxide, so that ambient light incident to the electronic device 10a from the outside may penetrate the transparent conductive layer TC1, thereby increasing the amount of photons received by the photodiode PD.

The electrode layer BL is, for example, disposed on the insulating layer IL2 and is electrically connected to the photodiode PD. That is, the electrode layer BL is electrically connected to the photodiode PD through the opening IL2_OP included in the insulating layer IL2. In this embodiment, the electrode layer BL is used as a voltage line, which can be used to apply a voltage to the photodiode PD, so that the electron holes and electron pairs in the photodiode PD are separated to generate carriers.

In some embodiments, the electronic device 10a may further include a scan line (not shown) and a read line (not shown). The scan line is disposed on, for example, the substrate SB and is electrically connected to the gate G of the active element TFT, and the scan line may be used to provide, for example, a scan signal to the corresponding active element TFT to turn it on. The read line is disposed on, for example, the substrate SB and is electrically connected to the source S of the active element TFT. The signal (carrier) generated by the photodiode PD may be transmitted to the read line via the source S, and the read line may transmit the signal (carrier) to an external circuit (not shown).

In this embodiment, the electrode layer E, the photodiode PD, and the transparent conductive layer TC1 may form a photoelectric element PE. The electrode layer E and the transparent conductive layer TC1 may respectively act as the cathode and the anode of the photoelectric element PE, and the photodiode PD is used to generate carriers. The electrode layer E is electrically connected to, for example, the drain D of the active element TFT, so that the carriers generated by the photodiode PD may be transferred to the drain D of the active element TFT through the electrode layer E and then may be transferred to the read line through the source S of the active element TFT. The transparent conductive layer TC1 is electrically connected to, for example, the electrode layer BL, so that the photodiode PD may receive the voltage applied from the electrode layer BL to generate carriers.

The transparent conductive layer TC2 is disposed on, for example, the insulating layer IL2 and contacts the electrode layer BL. In this embodiment, the transparent conductive layer TC2 is disposed on the electrode layer BL, that is, the electrode layer BL is located between the transparent conductive layer TC2 and the photoelectric element PE in the normal direction n of the substrate SB. The electrode layer BL has, for example, a side edge BLE, and the transparent conductive layer TC2 also has, for example, a side edge TC2E. In this embodiment, the side edge TC2E of the transparent conductive layer TC2 is indented from the side edge BLE of the electrode layer BL. In some embodiments, the side edge TC2E of the transparent conductive layer TC2 is flush with the side edge BLE of the electrode layer BL. For instance, a distance W and a distance W1 between the side edge BLE of the electrode layer BL and the side edge TC2E of the transparent conductive layer TC2 in a first direction d1 may be between, for example, 0 μm and 0.5 μm (0 μm≤W≤0.5 μm). The abovementioned first direction d1 is the extending direction of the substrate SB, for example, and is orthogonal to the normal direction n of the substrate SB, for example, but the disclosure is not limited thereto. To be specific, in this embodiment, the distance W between a top end point BLE_T of the side edge BLE and a bottom end point TC2E_B of the side edge TC2E in the first direction d1 and the distance W1 between a bottom end point TC2E_B1 of the side edge TC2E and a top end point BLE_T1 of the side edge BLE in the first direction d1 may be between, for example, 0 μm and 0.5 μm (0 μm≤W≤0.5 μm), as shown in FIG. 2. In some embodiments, the distance W may be different from the distance W1, but the disclosure is not limited thereto. It is noted that although in this embodiment, it is shown that the electrode layer BL is located between the transparent conductive layer TC2 and the photoelectric element PE in the normal direction n of the substrate SB, but the disclosure is not limited thereto. In other embodiments, the electrode layer BL may be located on the surface of the transparent conductive layer TC2 away from the photoelectric element PE, that is, the transparent conductive layer TC2 may be located between the electrode layer BL and the photoelectric element PE in the normal direction n of the substrate SB.

In some embodiments, the electronic device 10a further includes an insulating layer IL3, an insulating layer IL4, or further includes an insulating layer IL5.

The insulating layer IL3 is, for example, disposed on the insulating layer IL2 and has an opening IL3_OP exposing part of the photodiode PD. To be specific, in this embodiment, the opening IL3_OP of the insulating layer IL3 communicates with the opening IL2_OP of the insulating layer IL2 to form an opening OP to expose part of the photoelectric element PE together. In addition, the insulating layer IL3, for example, has a planarized surface away from the insulating layer IL2, thereby facilitating the formation of subsequent film layers. A material of the insulating layer IL3 may include, for example, an organic material (e.g., polyimide resin, epoxy resin, or acrylic resin), but the disclosure is not limited thereto.

The insulating layer IL4 is disposed on the insulating layer IL3, for example, and covers the photodiode PD, the electrode layer BL, and the transparent conductive layer TC2, for example, for protection. A material of the insulating layer IL4 may include, for example, an inorganic material (e.g., silicon oxide, silicon nitride, silicon oxynitride, or a stack layer having at least two of the above materials), an organic material (e.g., polyimide resin, epoxy resin, or acrylic resin), or combinations of the foregoing, but the disclosure is not limited thereto.

The insulating layer IL5 is disposed on the insulating layer IL4, for example. In some embodiments, the insulating layer IL5 may be disposed corresponding to the photoelectric element PE. To be specific, in the normal direction n of the substrate SB, the insulating layer IL5 and the photoelectric element PE at least partially overlap. The insulating layer IL5, for example, has a planarized surface away from the insulating layer IL4, thereby facilitating the formation of subsequent film layers. A material of the insulating layer IL5 may include, for example, an organic material (e.g., polyimide resin, epoxy resin, or acrylic resin), but the disclosure is not limited thereto. It should be noted that in other embodiments, the insulating layer IL5 may not be provided.

In some embodiments, the substrate SB includes an active area AA and a peripheral area PA, and the peripheral area PA is disposed on at least one side of the active area AA. For instance, the peripheral area PA may surround the active area AA, but the disclosure is not limited thereto. In this embodiment, the photodiode PD and the active element TFT are disposed in the active area AA, for example, and the metal layer M1 disposed in the peripheral area PA may be formed in the same process as the gate G of the active element TFT, and the two belong to the same layer, but the disclosure is not limited thereto.

In this embodiment, a contact pad PAD is disposed in the peripheral area PA. Since the insulating layer IL3 is not disposed in the peripheral area PA, the contact pad PAD is disposed on the insulating layer IL2. The contact pad PAD may be connected to external circuits such as a gate driving circuit (not shown), a source driving circuit (not shown), a flexible circuit board (not shown), or a chip (not shown), to control the active element TFT disposed in the active area AA, for example, but the disclosure is not limited thereto. A material of the contact pad PAD may include, for example, metals, alloys, metal oxides, or combinations thereof, but the disclosure is not limited thereto. In this embodiment, the contact pad PAD includes a laminated structure of a transparent conductive layer PADT (including metal oxide, which is, for example, indium tin oxide) and a metal layer PADM (including metal), and the transparent conductive layer PADT is disposed on the metal layer PADM, for example, to reduce the corrosion of the metal layer PADM due to oxidation, but the disclosure is not limited thereto. In this embodiment, the transparent conductive layer PADT in the contact pad PAD and the transparent conductive layer TC2 belong to the same layer, and the metal layer PADM in the contact pad PAD and the electrode layer BL belong to the same layer.

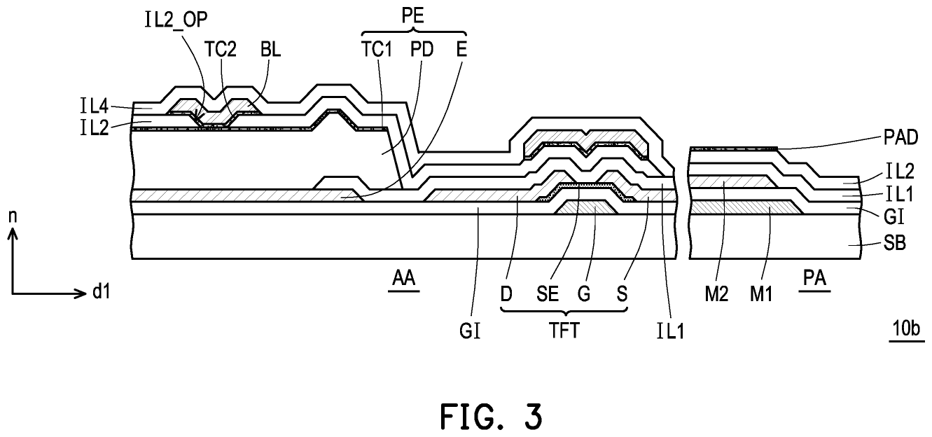

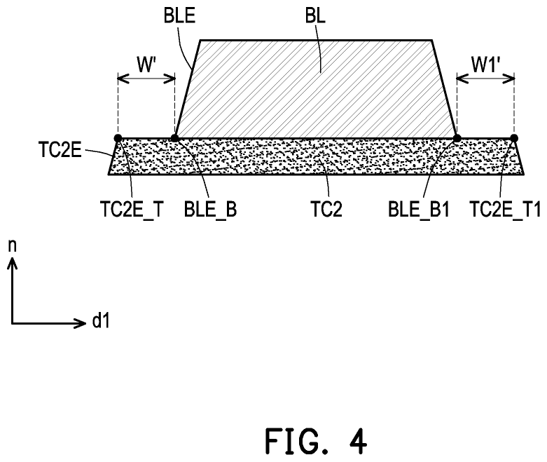

FIG. 3 is a schematic cross-sectional view of a portion of an electronic device according to another embodiment of the disclosure, and FIG. 4 is a schematic top view of portions of an electrode layer and a transparent conductive layer in the electronic device according to an embodiment of the disclosure. It should be mentioned that the reference numbers and some content provided in the embodiments shown in FIG. 1 and FIG. 2 may be applied in the embodiments shown in FIG. 3 and FIG. 4, where the same or similar reference numbers serve to denote the same or similar elements, and the description of the same technical content is omitted.

With reference to FIG. 3 and FIG. 4 together, the main difference between an electronic device 10b provided in this embodiment and the aforementioned electronic device 10a is that the transparent conductive layer TC2 of the electronic device 10b is disposed between the photodiode PD and the electrode layer BL.

In this embodiment, the side edge TC2E of the transparent conductive layer TC2 is indented from the side edge BLE of the electrode layer BL. In some embodiments, the side edge TC2E of the transparent conductive layer TC2 is flush with the side edge BLE of the electrode layer BL. For instance, a distance W′ and a distance W1′ between the side edge TC2E of the transparent conductive layer TC2 and the side edge BLE of the electrode layer BL in the first direction d1 may also be between, for example, 0 μm and 0.5 μm (0 μm≤W≤0.5 μm). To be specific, in this embodiment, the distance W′ between a top end point TC2E_T of the side edge TC2E and a bottom end point BLE_B of the side edge BLE in the first direction d1 and the distance W1′ between a bottom end point BLE_B1 of the side edge BLE and a top end point TC2E_T1 of the side edge TC2E in the first direction d1 may be between, for example, 0 μm and 0.5 μm (0 μm≤W≤0.5 μm), as shown in FIG. 4. In some embodiments, the distance W′ may be different from the distance W1′, but the disclosure is not limited thereto. It is noted that although in this embodiment, it is shown that the transparent conductive layer TC2 is located between the photodiode PD and the electrode layer BL in the normal direction n of the substrate SB, but the disclosure is not limited thereto. In other embodiments, the transparent conductive layer TC2 may be located on the surface of the electrode layer BL away from the photoelectric element PE, that is, the electrode layer BL may be located between the transparent conductive layer TC2 and the photoelectric element PE in the normal direction n of the substrate SB.

The electronic device 10b of this embodiment and the aforementioned electronic device 10a also exhibit the following differences.

In this embodiment, the electrode layer E is disposed between the insulating layer IL1 and the gate insulating layer GI and is formed in the same process as the source S and the drain D of the active element TFT, and the three belong to the same layer. Therefore, the electrode layer E may directly contact and thus be electrically connected to the drain D, for example. In addition, a metal layer M2 disposed in the peripheral area PA may also be formed in the same process as the source S and the drain D of the active element TFT, and the three belong to the same layer.

Further, in this embodiment, the contact pad PAD has a single-layer structure, and the material of the contact pad PAD is metal oxide, but the disclosure is not limited thereto.

In addition, in this embodiment, the electronic device 10b does not include the insulating layer IL3 nor the insulating layer IL5.

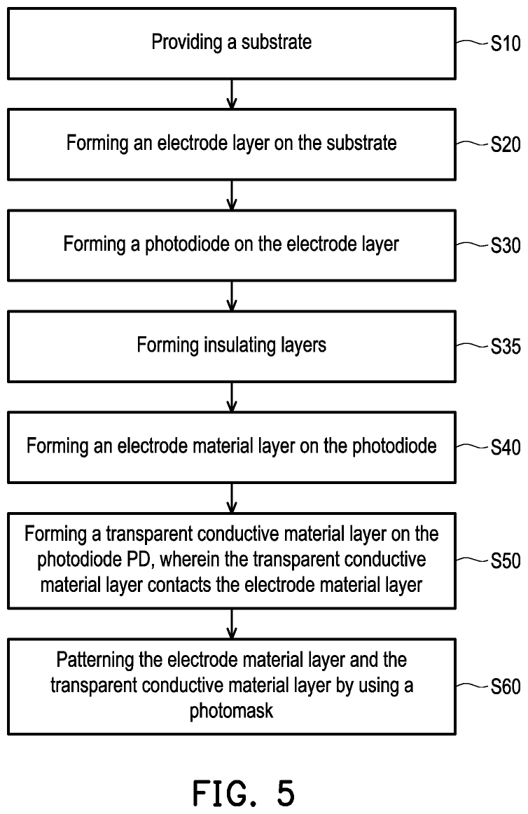

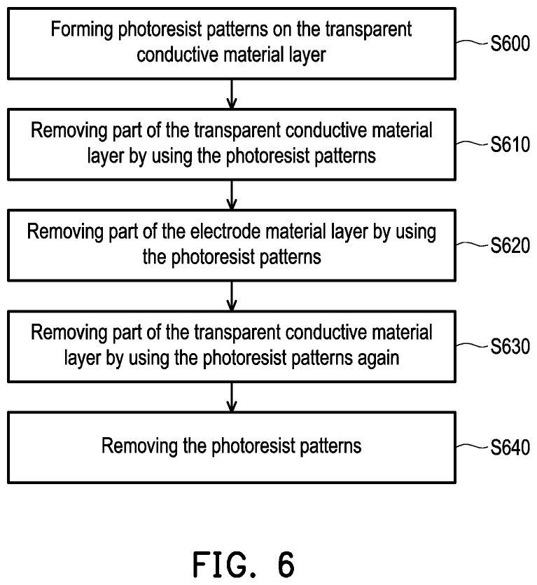

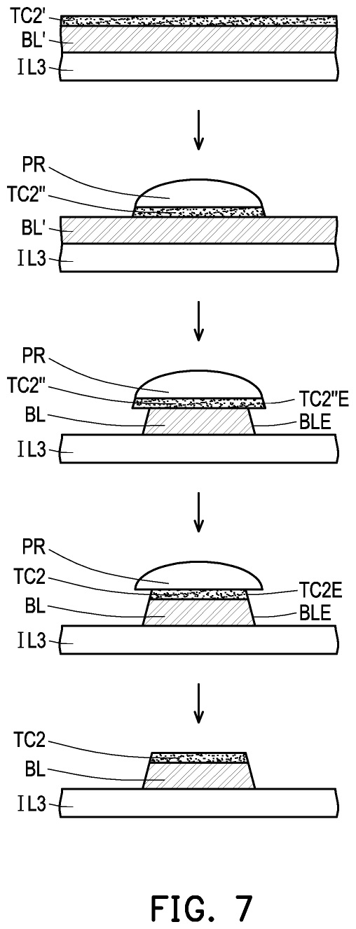

FIG. 5 is a flow chart of a manufacturing process of a portion of an electronic device according to an embodiment of the disclosure, which is, for example, a manufacturing process of a portion of the electronic device 10a. It should be noted that the flow chart shown in FIG. 5 is only an example and is not used to limit the manufacturing steps of the electronic device 10a. FIG. 6 is a flow chart of a manufacturing process of portions of an electrode layer and a transparent conductive layer according to an embodiment of the disclosure, and FIG. 7 is a schematic cross-sectional view of the manufacturing process of portions of the electrode layer and the transparent conductive layer according to an embodiment of the disclosure.

In step S10, the substrate SB is provided. The substrate SB includes, for example, the active area AA and the peripheral area PA. For the materials included in the substrate SB, reference may be made to the foregoing embodiments, and description thereof is not repeated herein.

In step S20, the electrode layer E is formed on the substrate SB. The electrode layer E may be formed on the substrate SB by, for example, physical vapor deposition, metal chemical vapor deposition, or other suitable processes, but the disclosure is not limited thereto. For the materials included in the electrode layer E, reference may be made to the foregoing embodiments, and description thereof is not repeated herein. For instance, the process of forming the electrode layer E may be performed after the source S and the drain D of the active element TFT are formed, and the material of the electrode layer E may include metal oxide or metal. Alternatively, the electrode layer E may be formed, for example, in the same process as the source S and the drain D of the active element TFT, and the material of the electrode layer E may include metal.

In step S30, the photodiode PD is formed on the electrode layer E. The photodiode PD may be formed on the electrode layer E by chemical vapor deposition or other suitable processes, for example, but the disclosure is not limited thereto. For the materials included in the photodiode PD, reference may be made to the foregoing embodiments, and description thereof is not repeated herein.

In step S40, an electrode material layer BL′ is formed on the photodiode PD. The electrode material layer BL′ may be fully formed on the photodiode PD by, for example, physical vapor deposition, metal chemical vapor deposition, or other suitable processes, but disclosure is not limited thereto. The electrode material layer BL′ is used to form the electrode layer BL mentioned in the foregoing embodiments, and therefore, for the materials included in the electrode material layer BL′, reference may be made to the foregoing embodiments, and description thereof is not repeated herein.

In step S50, a transparent conductive material layer TC2′ is formed on the photodiode PD, where the transparent conductive material layer TC2′ contacts the electrode material layer BL′. The transparent conductive material layer TC2′ may be fully formed on the photodiode PD by, for example, physical vapor deposition, metal chemical vapor deposition, or other suitable processes, but disclosure is not limited thereto. The transparent conductive material layer TC2′ is used to form the transparent conductive layer TC2 mentioned in the foregoing embodiments, and therefore, for the materials included in the transparent conductive material layer TC2′, reference may be made to the foregoing embodiments, and description thereof is not repeated herein. In this embodiment, the electrode material layer BL′ is formed before the transparent conductive material layer TC2′ is formed. Therefore, the electrode material layer BL′ is located between the transparent conductive material layer TC2′ and the photodiode PD in the normal direction n of the substrate SB, but the disclosure is not limited thereto.

In some embodiments, the manufacturing method of the electronic device 10a further includes performing step S35 after step S30 and before step S40. In step S35, the insulating layer IL2 and the insulating layer IL3 are formed after the photodiode PD is formed. Connected openings OP are formed in the insulating layer IL2 and the insulating layer IL3, and part of the electrode material layer BL′ and the transparent conductive material layer TC2′ fill the openings OP, as shown in FIG. 1. The insulating layer IL2 and the insulating layer IL3 may be formed on the photodiode PD by chemical vapor deposition or other suitable processes, for example, and the connected openings OP formed in the insulating layer IL2 and the insulating layer IL3 may be formed by a patterning process, but the disclosure is not limited thereto. For the materials included in the insulating layer IL2 and the insulating layer IL3, reference may be made to the foregoing embodiments, and description thereof is not repeated herein. Based on the above, after step S35 is performed, the electrode material layer BL′ formed in step S40 and the transparent conductive material layer TC2′ formed in step S50 may be disposed on the insulating layer IL3 and may be electrically connected to the photodiode PD through the openings OP.

In step S60, the electrode material layer BL′ and the transparent conductive material layer TC2′ are patterned by using a photomask to form the electrode layer BL and the transparent conductive layer TC2. To be specific, a photoresist is coated on the electrode material layer BL′ and the transparent conductive material layer TC2′, and then a photoresist pattern PR may be formed after the same photomask is used for exposure, development, and other operations. With reference to FIG. 6 and FIG. 7 together again, the electrode material layer BL′ and the transparent conductive material layer TC2′ are further patterned by using the photoresist pattern PR, and the following steps may be included. In the following steps, the patterning of the electrode material layer BL′ and the transparent conductive material layer TC2′ includes at least performing a first etching step and a second etching step capable of respectively enabling one of the electrode material layer BL′ and the transparent conductive material layer TC2′ to be patterned and enabling the other one of the electrode material layer BL′ and the transparent conductive material layer TC2′ to be patterned.

In step S600, the photoresist pattern PR is formed on the transparent conductive material layer TC2′. A plurality of photoresist patterns PR are provided, for example, to expose part of the transparent conductive material layer TC2′ to be removed.

In step S610, part of the transparent conductive material layer TC2′ is removed by using the photoresist patterns PR. Part of the transparent conductive material layer TC2′ may be removed by, for example, an etching process (first etching step). In this embodiment, part of the transparent conductive material layer TC2′ is removed by a wet etching process, where the used etching solution includes oxalic acid, but the disclosure is not limited thereto. After part of the transparent conductive material layer TC2′ is removed, a transparent conductive material layer TC2″ is formed, and part of the electrode material layer BL′ is exposed.

In step S620, part of the electrode material layer BL′ is removed by using the photoresist patterns PR to form the electrode layer BL. Part of the electrode material layer BL′ may be removed by, for example, an etching process (second etching step). In this embodiment, part of the electrode material layer BL′ is removed by a wet etching process, where the etching solution used includes aluminum hydroxide, but the disclosure is not limited thereto.

In step S630, part of the transparent conductive material layer TC2″ is removed by using the photoresist patterns PR again to form a transparent conductive layer TC2. Part of the transparent conductive material layer TC2″ may be removed by, for example, an etching process (third etching step). In this embodiment, part of the transparent conductive material layer TC2″ is removed by a wet etching process, where the used etching solution includes oxalic acid, but the disclosure is not limited thereto. After step S620 is performed, the third etching step is performed after the second etching step, such that part of the transparent conductive material layer TC2″ is removed. After step S620 is performed, the side edge TC2″E of the transparent conductive material layer TC2″ tends to exceed the side edge BLE of the formed electrode layer BL to form a chamfer. Therefore, after part of the transparent conductive material layer TC2″ is removed by performing step S630, the side edge TC2E of the formed transparent conductive layer TC2 may be flush with or further indented from the side edge BLE of the electrode layer BL, and the generation of chamfering is thus reduced. For instance, the distance W between the top end point BLE_T of the side edge BLE and the bottom end point TC2E_B of the side edge TC2E in the first direction d1 may be between, for example, 0 μm and 0.5 μm. (0 μm≤W≤0.5 μm), but it is not limited thereto.

In step S640, the photoresist patterns PR are removed. After the photoresist patterns PR are removed, the transparent conductive layer TC2 is exposed, and the subsequent process may continue to proceed. For instance, the insulating layer IL4 may be formed on the transparent conductive layer TC2. It should be noted that the electrode material layer BL′ and the transparent conductive material layer TC2′ disposed in the peripheral area PA respectively form the metal layer PADM and the transparent conductive layer PADT through the aforementioned steps as well to act as the contact pad PAD. Herein, the transparent conductive layer PADT is disposed on the metal layer PADM, so as to reduce the corrosion of the metal layer PADM due to oxidation, as shown in FIG. 1, but the disclosure is not limited thereto.

The manufacturing process of the electronic device 10a is completed thus far. It should be noted that although the manufacturing method of the electronic device 10a of this embodiment is described by taking the above method as an example, the manufacturing method of the electronic device 10a of the disclosure is not limited thereto, and the abovementioned steps may be deleted or other steps may be added according to needs. Further, the above steps may be adjusted in order according to needs.

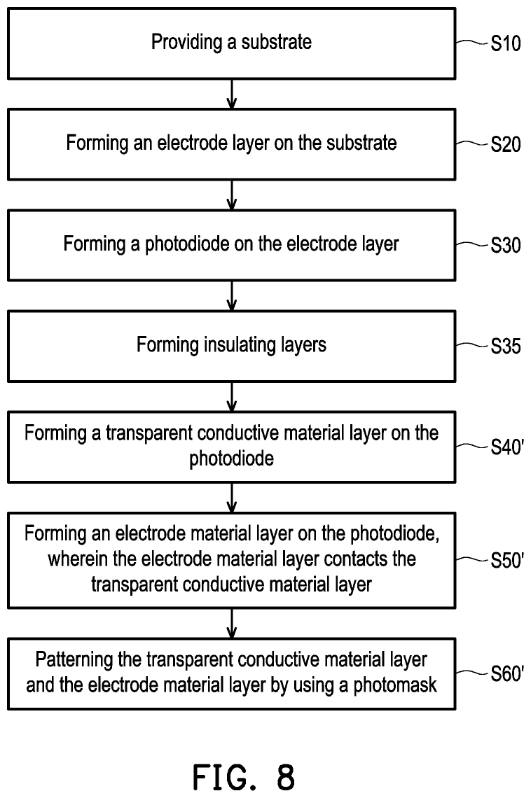

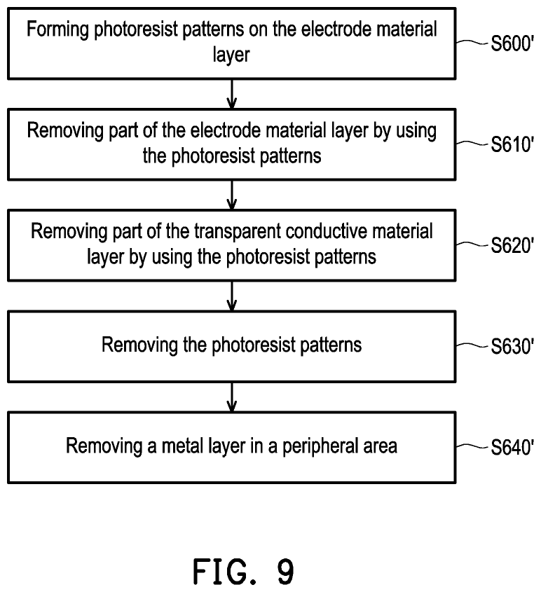

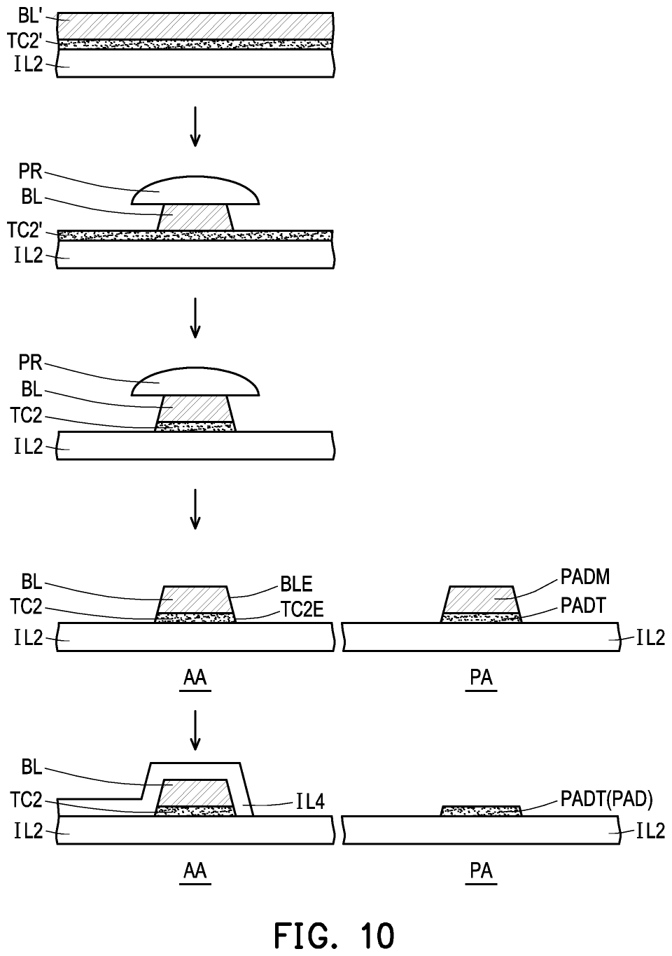

FIG. 8 is a flow chart of a manufacturing process of a portion of an electronic device according to an embodiment of the disclosure, which is, for example, a manufacturing process of a portion of the electronic device 10b. It should be mentioned that the reference numbers and some content provided in the embodiment shown in FIG. 5 may be applied in the embodiment shown in FIG. 8, where the same or similar reference numbers serve to denote the same or similar elements, and the description of the same technical content is omitted. It should be noted that the flow chart shown in FIG. 8 is only an example and is not used to limit the manufacturing steps of the electronic device 10b. FIG. 9 is a flow chart of a manufacturing process of portions of an electrode layer and a transparent conductive layer according to another embodiment of the disclosure, and FIG. 10 is a schematic cross-sectional view of the manufacturing process of portions of the electrode layer and the transparent conductive layer according to another embodiment of the disclosure.

The main difference between the manufacturing method of the electronic device 10b shown in FIG. 8 and the aforementioned manufacturing method of the electronic device 10a is that the electrode material layer BL′ is formed after the transparent conductive material layer TC2′ is formed.

For step S10 to step S30, reference may be made to the foregoing embodiments, and description thereof is not repeated herein. It should be noted that in step S20, the electrode layer E of the electronic device 10b is formed in the same process as the source S and the drain D of the active element TFT.

In step S40′, the transparent conductive material layer TC2′ is formed on the photodiode PD. For the formation of the transparent conductive material layer TC2′, reference may be made to the foregoing embodiments, and description thereof is not repeated herein.

In step S50′, the electrode material layer BL′ is formed on the photodiode PD, where the electrode material layer BL′ contacts the transparent conductive material layer TC2′. For the formation of the electrode material layer BL′, reference may be made to the foregoing embodiments, and description thereof is not repeated herein. In this embodiment, the electrode material layer BL′ is formed after the transparent conductive material layer TC2′ is formed. Therefore, the transparent conductive material layer TC2′ is located between the electrode material layer BL′ and the photodiode PD in the normal direction n of the substrate SB, but the disclosure is not limited thereto.

In some embodiments, the manufacturing method of the electronic device 10b further includes performing step S35 after step S30 and before step S40′. In step S35, the insulating layer IL2 is formed after the photodiode PD is formed. The opening IL2_OP is formed in the insulating layer IL2, and the transparent conductive material layer TC2′ and the electrode material layer BL′ fill the opening IL2_OP, as shown in FIG. 3. For the formation of the insulating layer IL2 and the opening IL2_OP, reference may be made to the foregoing embodiments, and description thereof is not repeated herein. Based on the above, after step S35 is performed, the transparent conductive material layer TC2′ formed in step S40′ and the electrode material layer BL′ formed in step S50′ may be disposed on the insulating layer IL2 and may be electrically connected to the photodiode PD through the opening IL2_OP.

In step S60′, the transparent conductive material layer TC2′ and the electrode material layer BL′ are patterned by using a photomask to form the transparent conductive layer TC2 and the electrode layer BL. To be specific, a photoresist is coated on the electrode material layer BL′ and the transparent conductive material layer TC2′, and then a photoresist pattern PR may be formed after the same photomask is used for exposure, development, and other operations. With reference to FIG. 9 and FIG. 10 together again, the transparent conductive material layer TC2′ and the electrode material layer BL′ are further patterned by using the photoresist pattern PR, and the following steps may be included. In the following steps, the patterning of the transparent conductive material layer TC2′ and the electrode material layer BL′ includes at least performing the first etching step and the second etching step capable of respectively enabling one of the transparent conductive material layer TC2′ and the electrode material layer BL′ to be patterned and enabling the other one of the transparent conductive material layer TC2′ and the electrode material layer BL′ and to be patterned.

In step S600′, the photoresist pattern PR is formed on the electrode material layer BL′. A plurality of photoresist patterns PR are provided, for example, to expose part of the electrode material layer BL′ to be removed.

In step S610′, part of the electrode material layer BL′ is removed by using the photoresist patterns PR. Part of the electrode material layer BL′ may be removed by, for example, an etching process (first etching step). In this embodiment, part of the electrode material layer BL′ is removed by a wet etching process, where the etching solution used includes aluminum hydroxide, but the disclosure is not limited thereto. After part of the electrode material layer BL′ is removed, the electrode layer BL is formed, and part of the transparent conductive material layer TC2′ is exposed.

In step S620′, part of the transparent conductive material layer TC2′ is removed by using the photoresist patterns PR to form the transparent conductive layer TC2. Part of the transparent conductive material layer TC2′ may be removed by, for example, an etching process (second etching step). In this embodiment, part of the transparent conductive material layer TC2′ is removed by a wet etching process, where the used etching solution includes oxalic acid, but the disclosure is not limited thereto.

In step S630′, the photoresist patterns PR are removed. After the photoresist patterns PR are removed, the electrode layer BL is exposed, and the subsequent process may continue to proceed. For instance, the subsequent step S640′ may be performed or the insulating layer IL4 may be formed. It should be noted that in this embodiment, the electrode material layer BL′ and the transparent conductive material layer TC2′ disposed in the peripheral area PA respectively form the metal layer PADM and the transparent conductive layer PADT through the aforementioned steps as well. The metal layer PADM is disposed on the transparent conductive layer PADT.

In step S640′, the metal layer PADM in the peripheral area is removed. Since the metal layer PADM is exposed, it may be easily oxidized and corroded without protection. Therefore, in this embodiment, the metal layer PADM on the transparent conductive layer PADT is removed, so that the exposed transparent conductive layer PADT acts as the contact pad PAD for electrical connection with an external circuit.

The manufacturing process of the electronic device 10b is completed thus far. It should be noted that although the manufacturing method of the electronic device 10b of this embodiment is described by taking the above method as an example, the manufacturing method of the electronic device 10b of the disclosure is not limited thereto, and the abovementioned steps may be deleted or other steps may be added according to needs. Further, the above steps may be adjusted in order according to needs.

According to the above, the electrode layer and the transparent conductive layer included in the electronic device provided by the embodiments of the disclosure are formed by using the same photomask. Therefore, the number of photomasks used and the number of manufacturing processes can be reduced, so that the manufacturing costs of the electronic device provided by the embodiments of the disclosure may be reduced.

It will be apparent to those skilled in the art that various modifications and variations can be made to the disclosed embodiments without departing from the scope or spirit of the disclosure. In view of the foregoing, it is intended that the disclosure covers modifications and variations provided that they fall within the scope of the following claims and their equivalents.

What is claimed is:

1. An electronic device, comprising:
a substrate;
a first electrode layer, disposed on the substrate;
a photodiode, disposed on the first electrode layer and electrically connected to the first electrode layer;
an insulating layer, disposed on the photodiode;
a second electrode layer, disposed on the insulating layer and electrically connected to the photodiode; and
a first transparent conductive layer, disposed on the insulating layer and contacting the second electrode layer.

2. The electronic device according to claim 1, wherein the first transparent conductive layer is disposed on the second electrode layer.

3. The electronic device according to claim 2, wherein the second electrode layer has a first side edge, the first transparent conductive layer has a second side edge, the first side edge is adjacent to the second side edge, and the second side edge is indented from the first side edge.

4. The electronic device according to claim 2, wherein the second electrode layer has a first side edge, the first transparent conductive layer has a second side edge, the first side edge is adjacent to the second side edge, and the second side edge is flush with the first side edge.

5. The electronic device according to claim 1, wherein the first transparent conductive layer is disposed between the photodiode and the second electrode layer.

6. The electronic device according to claim 5, wherein the second electrode layer has a first side edge, the first transparent conductive layer has a second side edge, the first side edge is adjacent to the second side edge, and the first side edge is indented from the second side edge.

7. The electronic device according to claim 5, wherein the second electrode layer has a first side edge, the first transparent conductive layer has a second side edge, the first side edge is adjacent to the second side edge, and the first side edge is flush with the second side edge.

8. The electronic device according to claim 1, further comprising a second transparent conductive layer, wherein the second transparent conductive layer is disposed between the insulating layer and the photodiode.

9. The electronic device according to claim 1, wherein the second electrode layer has a first side edge, the first transparent conductive layer has a second side edge, the first side edge is adjacent to the second side edge, and a distance between the first side edge and the second side edge in a first direction is between 0 μm and 0.5 μm.

10. The electronic device according to claim 1, further comprising an active element, wherein the active element is disposed on the substrate and is electrically connected to the photodiode.

11. A manufacturing method of an electronic device, comprising:
providing a substrate;
forming a first electrode layer on the substrate;
forming a photodiode on the first electrode layer;
forming a second electrode material layer on the photodiode;
forming a first transparent conductive material layer on the photodiode, wherein the first transparent conductive material layer contacts the second electrode material layer; and
patterning, by using a photomask, the second electrode material layer and the first transparent conductive material layer.

12. The manufacturing method of the electronic device according to claim 11, wherein the second electrode material layer is formed before the first transparent conductive material layer is formed.

13. The manufacturing method of the electronic device according to claim 11, wherein the second electrode material layer is formed after the first transparent conductive material layer is formed.

14. The manufacturing method of the electronic device according to claim 11, further comprising forming an insulating layer after forming the photodiode.

15. The manufacturing method of the electronic device according to claim 14, wherein an opening is formed on the insulating layer, and the second electrode material layer and the first transparent conductive material layer fill the opening.

16. The manufacturing method of the electronic device according to claim 11, wherein patterning the second electrode material layer and the first transparent conductive material layer comprises performing a first etching step, such that one of the second electrode material layer and the first transparent conductive material layer is patterned.

17. The manufacturing method of the electronic device according to claim 16, further comprising performing a second etching step after the first etching step, such that the other one of the second electrode material layer and the first transparent conductive material layer is patterned.

18. The manufacturing method of the electronic device according to claim 17, further comprising performing a third etching step after the second etching step, such that part of the first transparent conductive material layer is removed.

19. The manufacturing method of the electronic device according to claim 11, wherein a plurality of photoresist patterns are formed in the step of patterning, by using the photomask, the second electrode material layer and the first transparent conductive material layer.

20. The manufacturing method of the electronic device according to claim 19, wherein the photoresist patterns are removed after the step of patterning, by using the photomask, the second electrode material layer and the first transparent conductive material layer is performed.
